(19) United States
(12) Patent Application Publication
(10) Pub. No.: US 2025/0373218 A1
(43) Pub. Date: Dec. 4, 2025

(54) METHODS FOR MANUFACTURING A BULK ACOUSTIC WAVE FILTER STRUCTURE WITH AIR CAVITY

(71) Applicant: Qorvo US, Inc., Greensboro, NC (US)

(72) Inventors: Paul Stokes, Orlando, FL (US); Jaime Gerardo Trujillo, McKinney, TX (US)

(21) Appl. No.: 19/215,515

(22) Filed: May 22, 2025

Related U.S. Application Data
(60) Provisional application No. 63/654,177, filed on May 31, 2024.

(51) Int. Cl. H03H 3/02; H03H 9/54

(52) U.S. Cl. CPC H03H 3/02; H03H 9/54

(57) ABSTRACT

Methods for manufacturing a bulk acoustic wave (BAW) filter structure with an air cavity are provided. More specifically, the methods described herein are related to manufacturing the same BAW filter structure described in U.S. Pat. No. 11,528,007 B2 by replacing the sacrificial release layer described therein with the air cavity. By replacing the sacrificial release layer with the air cavity, it is possible to reduce material losses and improve a quality factor (Q-factor) of the BAW filter structure, especially at higher frequencies.

### RELATED APPLICATIONS

This application claims the benefit of U.S. provisional patent application Ser. No. 63/654,177, filed on May 31, 2024, the disclosure of which is hereby incorporated herein by reference in its entirety.

### FIELD OF THE DISCLOSURE

The technology of the disclosure relates generally to methods for manufacturing a bulk acoustic wave (BAW) filter structure.

### BACKGROUND

Acoustic resonators, and particularly bulk acoustic wave (BAW) resonators, are used in many high-frequency communication applications. In particular, BAW resonators are often employed in filter networks that operate at frequencies above 1.5 GHZ and require a flat passband, have exceptionally steep filter skirts and squared shoulders at the upper and lower ends of the passband, and provide excellent rejection outside of the passband. BAW-based filters also have a relatively low insertion loss, tend to decrease in size as the frequency of operation increases, and are relatively stable over wide temperature ranges. As such, BAW-based filters are the filter of choice for many Third Generation (3G), Fourth Generation (4G), and Fifth Generation (5G) wireless devices. Most of these wireless devices support cellular, wireless fidelity (Wi-Fi), Bluetooth, and/or near field communications on the same wireless device, and as such, pose extremely challenging filtering demands. While these demands keep raising the complexity of the wireless devices, there is a constant need to improve the performance of BAW resonators and BAW-based filters as well as decrease the cost and size associated therewith.

U.S. Pat. No. 11,528,007 B2, entitled “BULK ACOUSTIC WAVE FILTER STRUCTURE WITH CONDUCTIVE BRIDGE FORMING ELECTRICAL LOOP WITH AN ELECTRODE,” describes a BAW filter structure with a conductive bridge forming an electrical loop with an electrode for reduced electrical losses. Specifically, the BAW filter structure includes a transducer with electrodes, a piezoelectric layer between the electrodes, and at least one conductive bridge offset from at least a portion of one of the electrodes by a sacrificial release layer (a.k.a. insulating volume), such as a sacrificial oxide. Studies have shown that the sacrificial release layer provided therein may suffer a degraded quality factor (Q-factor) at higher frequencies (e.g., >2.5 GHZ). As such, it is desirable to improve the Q-factor of the BAW filter structure at higher frequencies.

### SUMMARY

Aspects disclosed in the detailed description include methods for manufacturing a bulk acoustic wave (BAW) filter structure with an air cavity. More specifically, the methods described herein are related to manufacturing the same BAW filter structure as described in U.S. Pat. No. 11,528,007 B2 by replacing the sacrificial release layer described therein with the air cavity. By replacing the sacrificial release layer with the air cavity, it is possible to reduce material losses and improve a quality factor (Q-factor) of the BAW filter structure, especially at higher frequencies.

In one aspect a method for replacing solid material used in a top sacrificial release layer and a bottom sacrificial release layer of a BAW filter structure with a top air cavity and a bottom air cavity is provided. The method includes forming a top release hole through a top conductive bridge to reach the top sacrificial release layer sandwiched between the top conductive bridge and a top electrode. The method also includes forming a bottom release hole through a bottom electrode to reach the bottom sacrificial release layer sandwiched between the bottom electrode and a bottom conductive bridge. The method also includes etching away a solid material in the top sacrificial release layer to thereby create the top air cavity. The method also includes etching away the solid material in the bottom sacrificial release layer to thereby create the bottom air cavity. The method also includes filling the top release hole and the bottom release hole to thereby conceal the top air cavity and the bottom air cavity.

In another aspect, a method for manufacturing a BAW filter structure with a top air cavity and a bottom air cavity is provided. The method includes forming a piezoelectric layer. The method also includes forming a bottom electrode on one side of the piezoelectric layer. The method also includes forming a bottom conductive bridge and a bottom conductive bridge via in between the bottom electrode and the bottom conductive bridge. The method also includes creating the bottom air cavity in between the bottom conductive bridge and the bottom electrode. The method also includes bonding to a silicon (Si) wafer and flipping the BAW filter structure. The method also includes forming a top electrode on an opposite side of the piezoelectric layer. The method also includes forming a top conductive bridge and a top conductive bridge via in between the top electrode and the top conductive bridge. The method also includes creating the top air cavity in between the top conductive bridge and the top electrode.

In another aspect, a method for manufacturing a BAW filter structure with a top air cavity is provided. The method includes forming a piezoelectric layer. The method also includes forming a bottom electrode on one side of the piezoelectric layer. The method also includes forming a bottom conductive bridge and a bottom conductive bridge via in between the bottom electrode and the bottom conductive bridge. The method also includes forming a top electrode on an opposite side of the piezoelectric layer. The method also includes forming a top conductive bridge and a top conductive bridge via in between the top electrode and the top conductive bridge. The method also includes creating the top air cavity in between the top conductive bridge and the top electrode.

In another aspect, a BAW filter structure is provided. The BAW filter structure includes a piezoelectric layer. The BAW filter structure also includes a top electrode and a bottom electrode that are provided on opposing sides of the piezoelectric layer. The BAW filter structure also includes a top conductive bridge via provided on the top electrode. The BAW filter structure also includes a top conductive bridge conductively coupled to the top electrode by the top conductive bridge via. The BAW filter structure also includes a top sacrificial release layer formed by a solid material and sandwiched between the top conductive bridge and the top electrode. The BAW filter structure also includes a bottom conductive bridge via provided on the bottom electrode. The BAW filter structure also includes a bottom conductive bridge conductively coupled to the bottom electrode by the bottom conductive bridge via. The BAW filter structure also includes a bottom sacrificial release layer formed by the solid material and sandwiched between the bottom conductive bridge and the bottom electrode. The BAW filter structure also includes a top release hole penetrating the top conductive bridge to reach the top sacrificial release layer to allow the solid material in the top sacrificial release layer to be etched away to thereby create a top air cavity. The BAW filter structure also includes a bottom release hole penetrating the bottom electrode to reach the bottom sacrificial release layer to allow the solid material in the bottom sacrificial release layer to be etched away to thereby create a bottom air cavity.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1A is a schematic diagram of an exemplary side view of a bulk acoustic wave (BAW) filter structure as described in U.S. Pat. No. 11,528,007 B2;

FIG. 1B is a schematic diagram of an exemplary top-down view of the BAW filter structure of FIG. 1A;

FIG. 1C is a schematic diagram of an exemplary bottom-up view of the BAW filter structure of FIG. 1A;

FIGS. 2A-2C are exemplary side views illustrating multiple processing steps for replacing solid material in a sacrificial release layer(s) in the BAW filter structure of FIG. 1A with an air cavity;

FIG. 3 is a flowchart of an exemplary process for replacing the solid material in the sacrificial release layer(s) in the BAW filter structure of FIG. 1A with the air cavity;

FIGS. 4A-4F are exemplary side views illustrating multiple processing steps for manufacturing a BAW filter structure using an air cavity in a sacrificial release layer(s);

FIG. 5 is a flowchart of an exemplary process for manufacturing the BAW filter structure of FIGS. 4A-4F with the air cavity; and

FIG. 6 is a schematic diagram of an exemplary communication device wherein the BAW filter structures manufactured in the processes of FIGS. 3 and 5 can be provided.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include methods for manufacturing a bulk acoustic wave (BAW) filter structure with an air cavity. More specifically, the methods described herein are related to manufacturing the same BAW filter structure as described in U.S. Pat. No. 11,528,007 B2 by replacing the sacrificial release layer described therein with the air cavity. By replacing the sacrificial release layer with the air cavity, it is possible to reduce material losses and improve a quality factor (Q-factor) of the BAW filter structure, especially at higher frequencies.

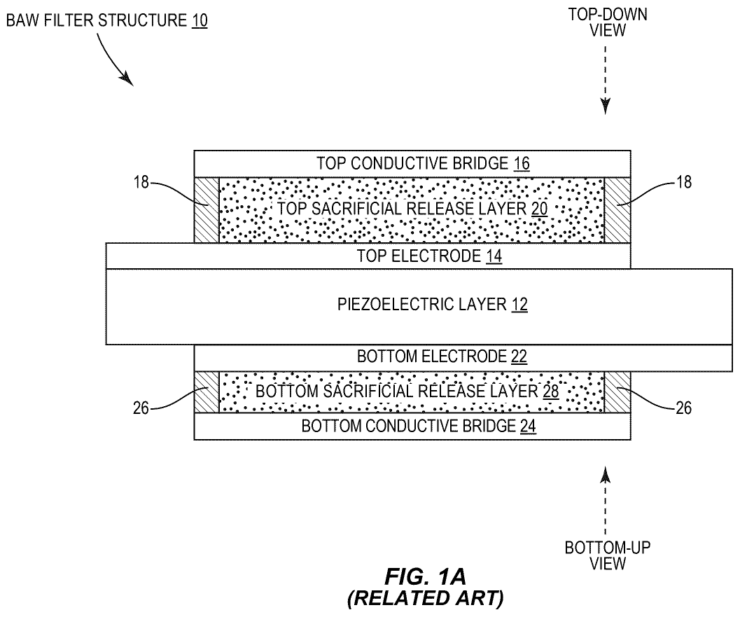

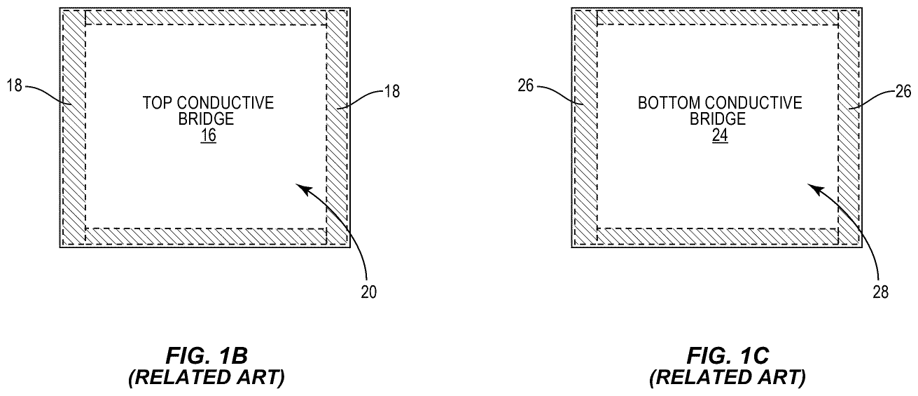

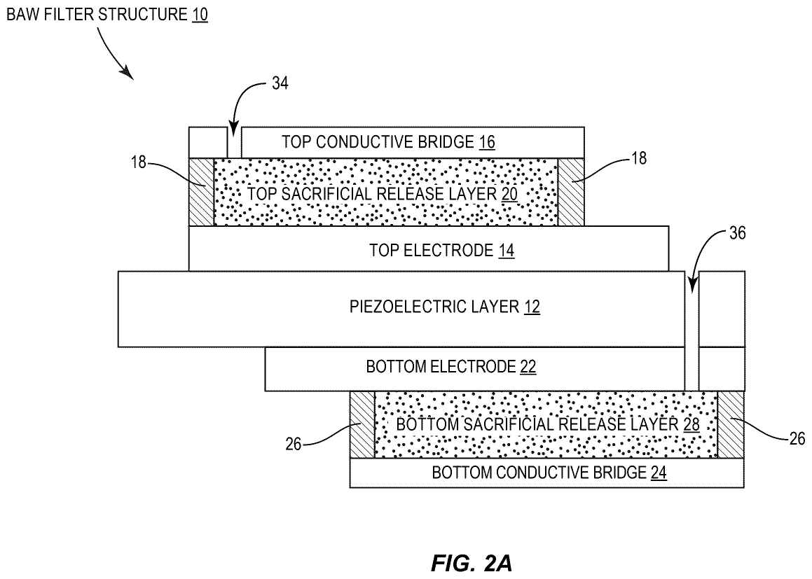

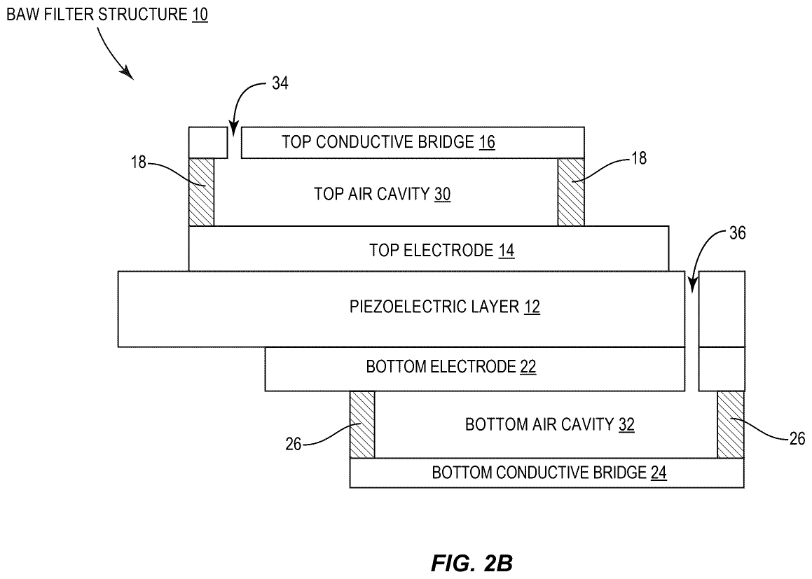

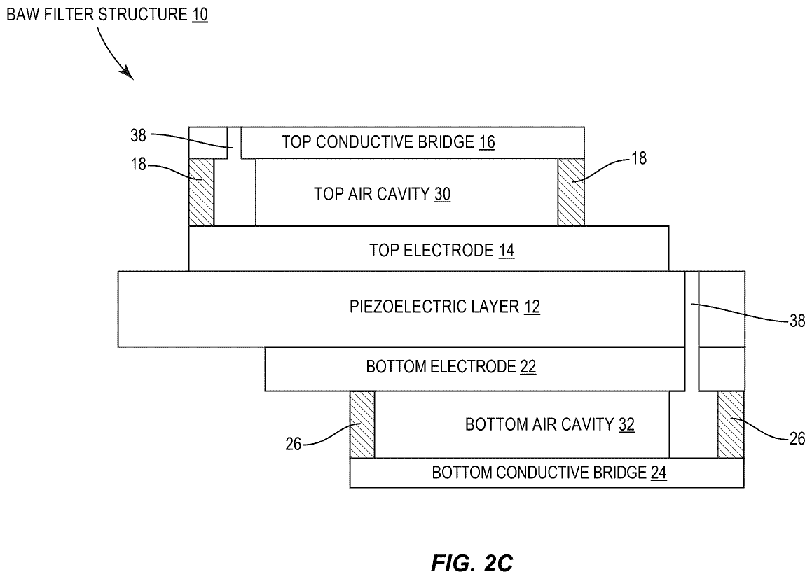

Before discussing methods of the present disclosure, starting at FIG. 2A, a brief overview of the BAW filter structure as described in U.S. Pat. No. 11,528,007 B2 is first with reference to FIGS. 1A-1C to help provide a better understanding of the BAW filter structure to be manufactured based on the methods disclosed herein.

FIG. 1A is a schematic diagram of an exemplary BAW filter structure 10 as described in U.S. Pat. No. 11,528,007 B2. The BAW filter structure 10 includes a piezoelectric layer 12, a top electrode 14, a top conductive bridge 16, a top conductive bridge via 18, a top sacrificial release layer 20, a bottom electrode 22, a bottom conductive bridge 24, a bottom conductive bridge via 26, and a bottom sacrificial release layer 28.

The top electrode 14 and the bottom electrode 22 are provided on opposing sides (e.g., top and bottom) of the piezoelectric layer 12. The top conductive bridge via 18 is provided on the top electrode 14 to conductively couple the top conductive bridge 16 to the top electrode 14. The bottom conductive bridge via 26 is provided on the bottom electrode 22 to conductively couple the bottom conductive bridge 24 to the bottom electrode 22.

FIG. 1B is a schematic diagram of an exemplary top-down view of the BAW filter structure 10 of FIG. 1A. Common elements between FIGS. 1A and 1B are shown therein with common element numbers and will not be re-described herein. As illustrated, the top conductive bridge via 18 is provided along four edges of the top conductive bridge 16. The top conductive bridge via 18 conceals the top sacrificial release layer 20 in between the top electrode 14 and the top conductive bridge 16.

FIG. 1C is a schematic diagram of an exemplary bottom-up view of the BAW filter structure 10 of FIG. 1A. Common elements between FIGS. 1A and 1C are shown therein with common element numbers and will not be re-described herein. As illustrated, the bottom conductive bridge via 26 is provided along four edges of the bottom conductive bridge 24. The bottom conductive bridge via 26 conceals the bottom sacrificial release layer 28 in between the bottom electrode 22 and the bottom conductive bridge 24.

With reference back to FIG. 1A, the top sacrificial release layer 20 and/or the bottom sacrificial release layer 28 can be made of either a solid material or an air cavity. Studies have shown that the air cavity can achieve an improved Q-factor and conductivity over the solid material, especially at higher frequencies (e.g., ≥2.5 GHZ). Moreover, the air cavity can avoid mechanically loading the BAW filter structure 10. As such, it is desirable to replace the top sacrificial release layer 20 and/or the bottom sacrificial release layer 28 with the air cavity.

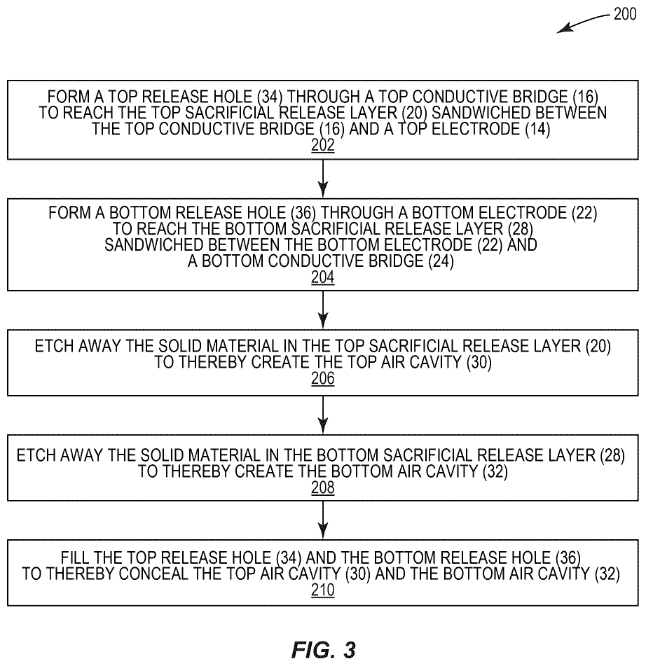

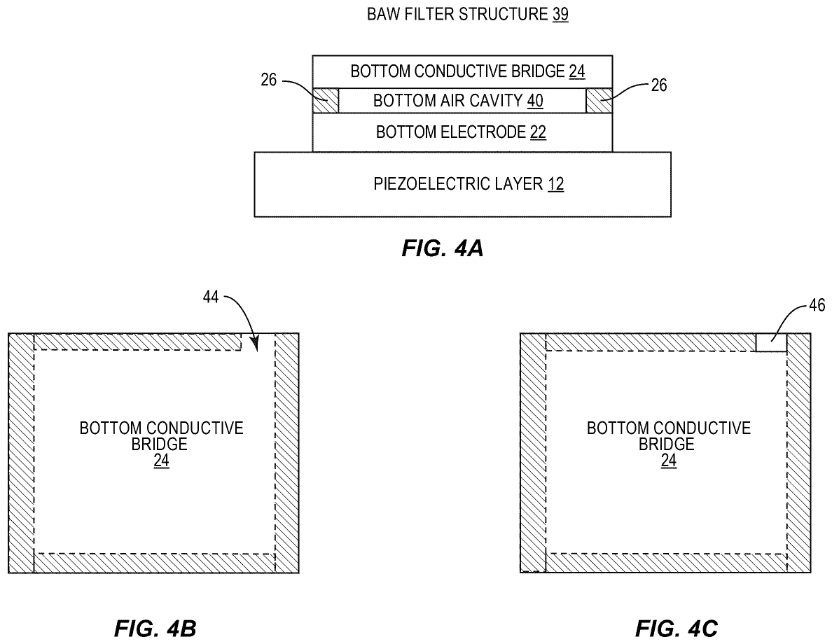

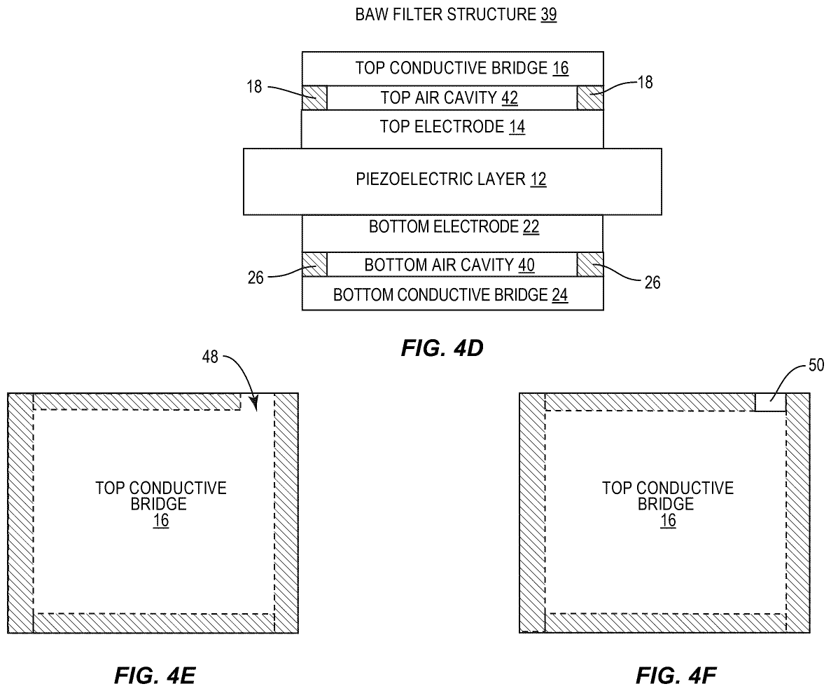

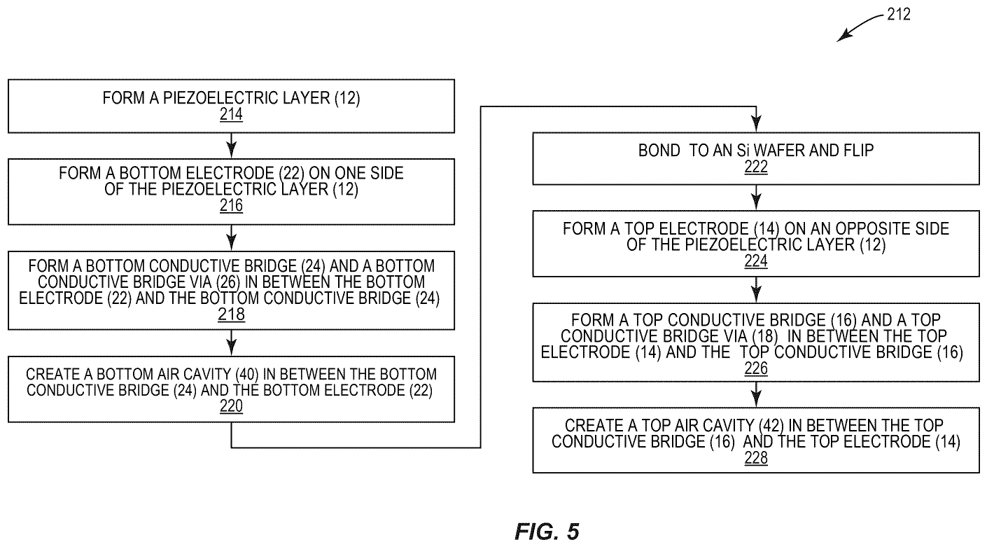

Embodiments disclosed herein include methods for manufacturing the BAW filter structure 10 of FIG. 1A using the air cavity as the top sacrificial release layer 20 and/or the bottom sacrificial release layer 28. Specifically, a first embodiment described in FIGS. 2A-2C and 3 is related to a method for replacing the solid material in the top sacrificial release layer 20 and the bottom sacrificial release layer 28 with the air cavity after the BAW filter structure 10 is already manufactured. In contrast, a second embodiment described in FIGS. 4A-4F and 5 is related to a method for manufacturing the BAW filter structure 10 using the air cavity as the top sacrificial release layer 20 and/or the bottom sacrificial release layer 28. Common elements between FIGS. 1A-1C, 2A-2C, 3, 4A-4F, and 5 are shown therein with common element numbers and will not be re-described herein.

FIGS. 2A-2C are exemplary side views illustrating a first embodiment of the present disclosure wherein multiple processing steps are performed for replacing solid material used in the top sacrificial release layer 20 and the bottom sacrificial release layer 28 in the BAW filter structure 10 of FIG. 1A with a top air cavity 30 and a bottom air cavity 32.

FIG. 2A illustrates a first processing step wherein a top release hole 34 and a bottom release hole 36 are formed. Specifically, the top release hole 34 penetrates the top conductive bridge 16 to reach the top sacrificial release layer 20, whereas the bottom release hole 36 penetrates the piezoelectric layer 12 and the bottom electrode 22 to reach the bottom sacrificial release layer 28.

FIG. 2B illustrates a second processing step wherein the solid material in the top sacrificial release layer 20 and the bottom sacrificial release layer 28 is etched away to create the top air cavity 30 and the bottom air cavity 32. In a non-limiting example, the solid material in the top sacrificial release layer 20 and the bottom sacrificial release layer 28 can be etched away using a hydrofluoric acid (HF) vapor etcher. In one embodiment, the solid material in the top sacrificial release layer 20 and the bottom sacrificial release layer 28 may be etched away sequentially. In another embodiment, the solid material in the top sacrificial release layer 20 and the bottom sacrificial release layer 28 may be etched away simultaneously.

FIG. 2C illustrates a third processing step wherein the top release hole 34 and the bottom release hole 36 are sealed. In a non-limiting example, the top release hole 34 and the bottom release hole 36 can be sealed by depositing oxide 38 into the top release hole 34 and the bottom release hole 36. Herein, the oxide 38 deposited into the top release hole 34 and the bottom release hole 36 may be tailored to prevent the oxide 38 from encroaching far into the top air cavity 30 and the bottom air cavity 32. Additionally, after sealing the top release hole 34 and the bottom release hole 36, the BAW filter structure 10 may be planarized and contacts may be made to access the BAW filter structure 10 electrically.

FIG. 3 is a flowchart of an exemplary process 200 summarizing the steps illustrated in FIGS. 2A-2C. Herein, the process 200 includes forming the top release hole 34 through the top conductive bridge 16 to reach the top sacrificial release layer 20 sandwiched between the top conductive bridge 16 and the top electrode 14 (step 202). The process 200 also includes forming the bottom release hole 36 through the bottom electrode 22 to reach the bottom sacrificial release layer 28 sandwiched between the bottom electrode 22 and the bottom conductive bridge 24 (step 204). The process 200 also includes etching away the solid material in the top sacrificial release layer 20 to thereby create the top air cavity 30 (step 206). The process 200 also includes etching away the solid material in the bottom sacrificial release layer 28 to thereby create the bottom air cavity 32 (step 208). The process 200 further includes filling the top release hole 34 and the bottom release hole 36 to thereby conceal the top air cavity 30 and the bottom air cavity 32 (step 210).

In contrast to replacing the solid material used in the top sacrificial release layer 20 and the bottom sacrificial release layer 28 in the BAW filter structure 10, it is also possible to manufacture a BAW filter structure with an air cavity from the ground up. In this regard, FIGS. 4A-4F are exemplary side views illustrating a second embodiment of the present disclosure wherein multiple processing steps are performed for manufacturing a BAW filter structure 39 with a bottom air cavity 40 and a top air cavity 42. Common elements between FIGS. 1A and 4A-4F are shown therein with common element numbers and will not be re-described herein.

According to FIG. 4A, the piezoelectric layer 12 is formed first and the bottom electrode 22 is provided on one side (e.g., bottom) of the piezoelectric layer 12. The bottom conductive bridge via 26 is provided on the bottom electrode 22 and the bottom conductive bridge 24 is then provided to sandwich the bottom conductive bridge via 26 between the bottom electrode 22 and the bottom conductive bridge 24.

FIGS. 4B and 4C are exemplary top-down views of the BAW filter structure 10 formed thus far. In FIG. 4B, a bottom side release hole 44 is formed concurrent to forming the bottom conductive bridge 24 to thereby create the bottom air cavity 40 in between the bottom conductive bridge 24 and the bottom electrode 22. In FIG. 4C, the bottom side release hole 44 is filled with oxide 46 to thereby conceal the bottom air cavity 40.

In an embodiment, the BAW filter structure 39 as formed in FIGS. 4A-4C is then fusion bonded to another silicon (Si) wafer and flipped over. Subsequently, the Si carrier may be removed to allow piezo patterning.

With reference to FIG. 4D, the top electrode 14 is now formed on an opposite side (e.g., top) of the piezoelectric layer 12. The top conductive bridge via 18 is provided on the top electrode 14 and the top conductive bridge 16 is then provided to sandwich the top conductive bridge via 18 between the top electrode 14 and the top conductive bridge 16.

FIGS. 4E and 4F are exemplary top-down views of the BAW filter structure 10 formed thus far. In FIG. 4E, a top side release hole 48 is formed concurrent to forming the top conductive bridge 16 to thereby create the top air cavity 42 in between the top conductive bridge 16 and the top electrode 14. In FIG. 4F, the top side release hole 48 is filled with oxide 50 to thereby conceal the top air cavity 42.

FIG. 5 is a flowchart of an exemplary process 212 summarizing the steps illustrated in FIGS. 4A-4F. Herein, the process 212 includes forming the piezoelectric layer 12 (step 214). The process 212 also includes forming the bottom electrode 22 on one side of the piezoelectric layer 12 (step 216). The process 212 also includes forming the bottom conductive bridge 24 and the bottom conductive bridge via 26 in between the bottom electrode 22 and the bottom conductive bridge 24 (step 218). The process 212 also includes creating the bottom air cavity 40 in between the bottom conductive bridge 24 and the bottom electrode 22 (step 220).

The process 212 further includes bonding to the Si wafer and flipping the BAW filter structure 10 produced thus far (step 222). The process 212 further includes forming the top electrode 14 on the opposite side of the piezoelectric layer 12 (step 224). The process 212 further includes forming the top conductive bridge 16 and the top conductive bridge via 18 in between the top electrode 14 and the top conductive bridge 16 (step 226). The process 212 further includes creating the top air cavity 42 in between the top conductive bridge 16 and the top electrode 14 (step 228).

In one embodiment, the process 212 may be adapted to create only the bottom air cavity 40 by performing steps 214 through 220. In another embodiment, the process 212 may be adapted to create only the top air cavity 42 by performing steps 224 through 228.

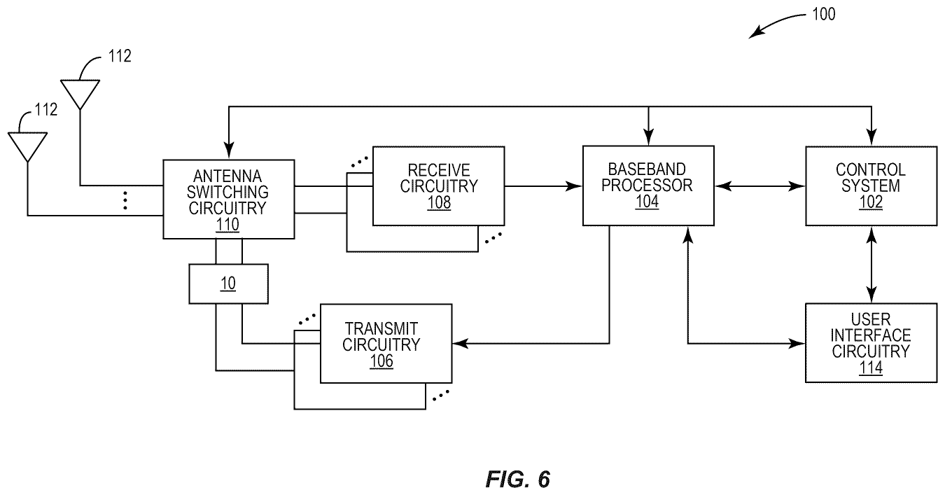

The BAW filter structure 10 as manufactured in the process 200 of FIG. 3 and the process 212 of FIG. 5 can be provided in a communication device to enable the embodiments described above. In this regard, FIG. 6 is a schematic diagram of an exemplary communication device 100 wherein the BAW filter structure 10 manufactured by the process 200 of FIG. 3 and the process 212 of FIG. 5 can be provided.

Herein, the communication device 100 can be any type of communication device, such as mobile terminal, smart watch, tablet, computer, navigation device, access point, base station (e.g., eNB, gNB, etc.), and like wireless communication devices that support wireless communications, such as cellular, wireless local area network (WLAN), Bluetooth, Ultra-wideband (UWB), and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

Those skilled in the art will recognize improvements and modifications to the embodiments of the present disclosure. All such improvements and modifications are considered within the scope of the concepts disclosed herein and the claims that follow.

What is claimed is:

1. A method for replacing solid material used in a top sacrificial release layer and a bottom sacrificial release layer of a bulk acoustic wave (BAW) filter structure with a top air cavity and a bottom air cavity comprising:
forming a top release hole through a top conductive bridge to reach the top sacrificial release layer sandwiched between the top conductive bridge and a top electrode;
forming a bottom release hole through a bottom electrode to reach the bottom sacrificial release layer sandwiched between the bottom electrode and a bottom conductive bridge;
etching away a solid material in the top sacrificial release layer to thereby create the top air cavity;
etching away the solid material in the bottom sacrificial release layer to thereby create the bottom air cavity; and
filling the top release hole and the bottom release hole to thereby conceal the top air cavity and the bottom air cavity.

2. The method of claim 1, wherein forming the bottom release hole comprises penetrating the bottom release hole through a piezoelectric layer sandwiched between the top electrode and the bottom electrode.

3. The method of claim 1, wherein etching away the solid material in the top sacrificial release layer and the bottom sacrificial release layer comprises etching away the solid material in the top sacrificial release layer and the bottom sacrificial release layer with a hydrofluoric acid (HF) vapor etcher.

4. The method of claim 1, wherein filling the top release hole and the bottom release hole comprises filling the top release hole and the bottom release hole by depositing oxide into the top release hole and the bottom release hole.

5. The method of claim 4, further comprising a tailored oxide deposition in the top release hole and the bottom release hole to prevent the oxide from encroaching far into the top air cavity and the bottom air cavity.

6. The method of claim 1, further comprising planarizing the BAW filter structure after filling the top release hole and the bottom release hole.

7. The method of claim 1, further comprising etching away the solid material in the top sacrificial release layer and the bottom sacrificial release layer sequentially.

8. The method of claim 1, further comprising etching away the solid material in the top sacrificial release layer and the bottom sacrificial release layer simultaneously.

9. A method for manufacturing a bulk acoustic wave (BAW) filter structure with a top air cavity and a bottom air cavity comprising:
forming a piezoelectric layer;
forming a bottom electrode on one side of the piezoelectric layer;
forming a bottom conductive bridge and a bottom conductive bridge via in between the bottom electrode and the bottom conductive bridge;
creating the bottom air cavity in between the bottom conductive bridge and the bottom electrode;
bonding to a silicon (Si) wafer and flipping the BAW filter structure;
forming a top electrode on an opposite side of the piezoelectric layer;
forming a top conductive bridge and a top conductive bridge via in between the top electrode and the top conductive bridge; and
creating the top air cavity in between the top conductive bridge and the top electrode.

10. The method of claim 9, wherein creating the bottom air cavity comprises:
forming a bottom side release hole in the bottom conductive bridge via;
performing vapor etching through the bottom side release hole to thereby create the bottom air cavity; and
filling the bottom side release hole to conceal the bottom air cavity.

11. The method of claim 10, further comprising forming the bottom side release hole and the bottom conductive bridge concurrently.

12. The method of claim 10, further comprising planarizing the BAW filter structure after filling the bottom side release hole.

13. The method of claim 9, wherein creating the top air cavity comprises:
forming a top side release hole in the top conductive bridge via;
performing vapor etching through the top side release hole to thereby create the top air cavity; and
filling the top side release hole to conceal the top air cavity.

14. The method of claim 13, further comprising forming the top side release hole and the top conductive bridge concurrently.

15. The method of claim 13, further comprising planarizing the BAW filter structure after filling the top side release hole.

16. The method of claim 9, further comprising flipping the BAW filter structure after creating the bottom air cavity and before forming the top electrode.

17. A method for manufacturing a bulk acoustic wave (BAW) filter structure with a top air cavity comprising:
forming a piezoelectric layer;
forming a bottom electrode on one side of the piezoelectric layer;
forming a bottom conductive bridge and a bottom conductive bridge via in between the bottom electrode and the bottom conductive bridge;
forming a top electrode on an opposite side of the piezoelectric layer;
forming a top conductive bridge and a top conductive bridge via in between the top electrode and the top conductive bridge; and
creating the top air cavity in between the top conductive bridge and the top electrode.

18. The method of claim 17, wherein creating the top air cavity comprises:
forming a top side release hole in the top conductive bridge via;
performing vapor etching through the top side release hole to thereby create the top air cavity; and
filling the top side release hole to conceal the top air cavity.

19. The method of claim 18, further comprising forming the top side release hole and the top conductive bridge concurrently.

20. The method of claim 18, further comprising planarizing the BAW filter structure after filling the top side release hole.

21. A bulk acoustic wave (BAW) filter structure comprising:
a piezoelectric layer;
a top electrode and a bottom electrode provided on opposing sides of the piezoelectric layer;
a top conductive bridge via provided on the top electrode;
a top conductive bridge conductively coupled to the top electrode by the top conductive bridge via;
a top sacrificial release layer formed by a solid material and sandwiched between the top conductive bridge and the top electrode;
a bottom conductive bridge via provided on the bottom electrode;
a bottom conductive bridge conductively coupled to the bottom electrode by the bottom conductive bridge via;
a bottom sacrificial release layer formed by the solid material and sandwiched between the bottom conductive bridge and the bottom electrode;
a top release hole penetrating the top conductive bridge to reach the top sacrificial release layer to allow the solid material in the top sacrificial release layer to be etched away to thereby create a top air cavity; and
a bottom release hole penetrating the bottom electrode to reach the bottom sacrificial release layer to allow the solid material in the bottom sacrificial release layer to be etched away to thereby create a bottom air cavity.
